(19) United States
(12) Patent Application Publication
(10) Pub. No.: US 2023/0180581 A1
(43) Pub. Date: Jun. 8, 2023

(54) DISPLAY SUBSTRATE, FABRICATION METHOD THEREFOR, AND DISPLAY APPARATUS

(71) Applicant: BOE Technology Group Co., Ltd., Beijing (CN)

(72) Inventors: Meng ZHAO, Beijing (CN); Yibing FAN, Beijing (CN)

(21) Appl. No.: 17/921,323

(22) PCT Filed: May 27, 2021
(86) PCT No.: PCT/CN2021/096425

§ 371 Date: Oct. 25, 2022

(30) Foreign Application Priority Data
Jun. 18, 2020 (CN) 202010562356.X

(51) Int. Cl. H10K 59/80; H10K 71/60; H10K 71/00

(52) U.S. Cl. CPC H10K 59/80523; H10K 59/80521; H10K 71/60; H10K 71/621; H10K 59/80

(57) ABSTRACT

Provided in the present disclosure are a display substrate, a fabrication method therefor, and a display apparatus. The method comprises: forming a pixel defining layer on the surface of one side of a substrate, said layer defining an opening; forming a light-emitting layer in the opening; forming a sacrificial layer and a photoresist layer on the surface of the light-emitting layer away from the substrate, the orthographic projection of the sacrificial layer on the substrate at least partially overlapping the orthographic projection of the opening on the substrate, and the photoresist layer being located on the surface of the sacrificial layer away from the substrate; forming a first metal layer on the surfaces of the pixel defining layer and the photoresist layer away from the substrate; removing the sacrificial layer, the photoresist layer, and the first metal layer located on the surface of the photoresist layer away from the substrate, and exposing the opening; and forming a second metal layer in the opening and on the surface of the first metal layer away from the substrate. A cathode of the display substrate fabricated by using the described method is thinner in the opening and thicker on the surface of the pixel defining layer. The light-emitting efficiency is high, and the voltage drop is relatively low. The display effect is good, and costs are low.

### CROSS REFERENCE TO RELATED APPLICATIONS

The present disclosure claims the priority to Chinese Patent Application No. 202010562356.X, filed to the Chinese Patent Office on Jun. 18, 2020 and entitled “METHOD FOR FABRICATING DISPLAY BACKBOARD, DISPLAY BACKBOARD AND DISPLAY APPARATUS”, which is incorporated in its entirety herein by reference.

### FIELD

The present disclosure relates to the technical field of display, and particularly relates to a display substrate, a fabrication method therefor, and a display apparatus.

### BACKGROUND

At present, an organic electro luminescent display (OLED) has gradually become the mainstream product in the display field because of its excellent performance such as low power consumption, high color saturation, a wide viewing angle, a low thickness and high flexibility, and can be widely used in terminal products such as smart phones, tablet computers and televisions.

### SUMMARY

In a first aspect, an embodiment of the present disclosure provides a method for fabricating a display substrate. The method includes: forming a pixel defining layer on a surface of one side of a substrate, the pixel defining layer defining an opening; forming a light-emitting layer on one side of the pixel defining layer away from the substrate; forming a sacrificial layer and a photoresist layer on a surface of the light-emitting layer away from the substrate, an orthographic projection of the sacrificial layer on the substrate at least partially overlapping an orthographic projection of the opening on the substrate, and the photoresist layer being located on a surface of the sacrificial layer away from the substrate; forming a first metal layer on surfaces of the pixel defining layer and the photoresist layer away from the substrate; removing the sacrificial layer, the photoresist layer, and the first metal layer located on the surface of the photoresist layer away from the substrate, and exposing the opening; and forming a second metal layer in the opening and on a surface of the first metal layer away from the substrate, the first metal layer and the second metal layer jointly constituting a cathode of the display substrate.

Optionally, the orthographic projection of the sacrificial layer on the substrate is located in an orthographic projection of the photoresist layer on the substrate.

Optionally, there is a gap between an outline of the orthographic projection of the photoresist layer on the substrate and an outline of the orthographic projection of the sacrificial layer on the substrate.

Optionally, a distance between a surface of the photoresist layer close to the substrate and a surface of the pixel defining layer away from the substrate is greater than a thickness of the first metal layer.

Optionally, the orthographic projection of the sacrificial layer on the substrate covers the orthographic projection of the opening on the substrate.

Optionally, the sacrificial layer satisfies at least one of the following conditions that: a material includes a fluorine-containing high-polymer material; and a thickness is 0.2 μm-1.5 μm.

Optionally, a thickness of the photoresist layer is 0.5 μm-2 μm.

Optionally, the forming the sacrificial layer and the photoresist layer on the surface of the light-emitting layer away from the substrate further includes: forming a first prefabricated film layer on the surfaces of the pixel defining layer and the light-emitting layer away from the substrate; forming an entire layer of second prefabricated film layer on a surface of the first prefabricated film layer away from the substrate; patterning the second prefabricated film layer through a composition process, to obtain the photoresist layer; and removing the first prefabricated film layer not covered with the photoresist layer, to obtain the sacrificial layer.

In a second aspect, an embodiment of the present disclosure provides a display substrate. The display substrate includes a substrate, a pixel defining layer, a light-emitting layer and a cathode. The pixel defining layer defines an opening. The cathode includes: a first metal layer, arranged on a surface of the pixel defining layer away from the substrate; and a second metal layer, arranged in the opening and on a surface of the first metal layer away from the substrate.

Optionally, a section of a part of the pixel defining layer between adjacent openings perpendicular to a surface of the substrate is a regular trapezoid.

The first metal layer only covers a top surface of the regular trapezoid.

Optionally, the second metal layer covers a top surface and a side wall of the first metal layer and a side wall of the regular trapezoid.

Optionally, a thickness of the first metal layer is not smaller than 10 nm.

Optionally, a thickness of the first metal layer is 20 nm-30 nm; and a thickness of the second metal layer is 5 nm-15 nm.

Optionally, a thickness of the first metal layer is greater than a thickness of the second metal layer.

In a third aspect, an embodiment of the present disclosure provides a display apparatus. The display apparatus includes the display substrate according to the second aspect.

### BRIEF DESCRIPTION OF THE DRAWINGS

FIG. 1 is a schematic flowchart of a fabrication method for a display substrate according to an embodiment of the present disclosure.

FIGS. 2A-2F each show a schematic structural diagram of a fabrication method for a display substrate after each step is completed according to an embodiment of the present disclosure.

FIG. 3 is a schematic diagram of a sectional structure of a sacrificial layer and a photoresist layer according to an embodiment of the present disclosure.

FIG. 4 is a schematic flowchart of forming a sacrificial layer and a photoresist layer on a surface of a light-emitting layer away from a substrate according to an embodiment of the present disclosure.

FIGS. 5A-5D each show a schematic structural diagram after each step of forming a sacrificial layer and a photoresist layer on a surface of a light-emitting layer away from a substrate is completed according to an embodiment of the present disclosure.

### DETAILED DESCRIPTION OF THE EMBODIMENTS

Mainstream products of an OLED are small-sized products such as a mobile phone screen. In related art, main constraints on application of an OLED substrate to a large-sized display apparatus (such as a notebook computer or other products) are light-emitting efficiency of an existing display substrate and an IR drop of a cathode in the display substrate. Specifically, in a commonly used top-emitting OLED substrate, a cathode usually uses an entire-surface metal film (such as a Mg/Ag film). However, due to a transmittance restriction, a thickness of the cathode cannot be too high, otherwise the thickness will influence light-emitting efficiency of the OLED substrate. However, since an entire surface of the cathode is evaporated on the OLED substrate, a Vss signal required by the cathode is input into the cathode from contact groove areas on two sides of a screen by bottom metal. When a thickness of the cathode is very low, a resistance of the cathode is great, and IR drop of an entire cathode surface is great, such that a great difference may be caused between a center and a periphery of a display frame.

In view of the above technical problems, a solution in the related art is usually to lay out a cathode, that is, to use a metal mask to fabricate a cathode that is thinner in a pixel center area (in an opening defined by a pixel defining layer of a display substrate) and thicker in a connection area between pixels (on a surface of the pixel defining layer), such that an overall resistance of the cathode may be reduced and a display effect is desirable. However, when the metal mask is used to fabricate the cathode, a metal film layer deposited on the metal mask cannot be removed from the mask, so one mask has to be scrapped after one cathode is fabricated, which is too high in cost and is not conducive to actual industrialization.

Embodiments of the present disclosure will be described in detail below. The embodiments described below are illustrative and only used for explaining the present disclosure, instead of being construed as limiting the present disclosure. If specific technologies or conditions are not indicated in the embodiments, technologies or conditions described in the literature in the field or product specifications should be followed. The reagents or instruments used herein are conventional products that may be obtained through market purchase if manufacturers are not indicated.

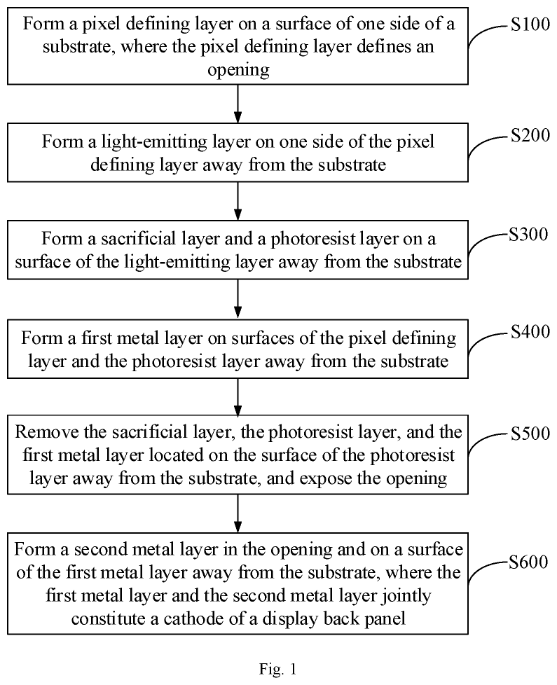

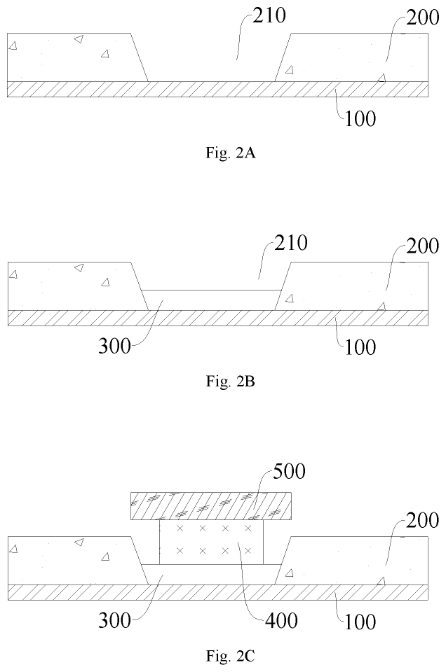

In an aspect of the present disclosure, the present disclosure provides a fabrication method for a display substrate. According to the embodiments of the present disclosure, with reference to FIGS. 1, 2A, 2B, 2C, 2D, 2E and 2F, the method may include the following steps.

S100: a pixel defining layer 200 is formed on a surface of one side of a substrate 100. The pixel defining layer 200 defines an opening 210 (with reference to FIG. 2A for a schematic structural diagram).

According to the embodiments of the present disclosure, a specific process of forming the pixel defining layer 200 defining the opening 210 on the surface of one side of the substrate 100 is not particularly limited and may be an evaporation or composition process for example, and specific process conditions and parameters may be flexibly selected by those skilled in the art according to actual requirements, which will not be repeated herein. In this way, operations are simple, convenient and easy to implement, and industrial production is feasible.

S200: a light-emitting layer 300 is formed on one side of the pixel defining layer 200 away from the substrate 100 (with reference to FIG. 2B for a schematic structural diagram).

According to the embodiments of the present disclosure, a specific process of forming the light-emitting layer 300 in the opening 210 may be ink-jet printing or vacuum evaporation, and specific process conditions and parameters may be flexibly selected by those skilled in the art according to actual requirements, which will not be repeated herein. In this way, operations are simple, convenient and easy to implement, and industrial production is feasible.

According to the embodiments of the present disclosure, specific materials, thicknesses, etc. of the substrate 100, the pixel defining layer 200, the light-emitting layer 300, etc. may be flexibly selected by those skilled in the art according to actual requirements, which will not be repeated herein.

It should be noted that the light-emitting layer 300 may specifically include a plurality of layers, such as an electron transport layer, a light-emitting material layer, a hole transport layer, etc.

S300: a sacrificial layer 400 and a photoresist layer 500 are formed on a surface of the light-emitting layer 300 away from the substrate 100. An orthographic projection of the sacrificial layer 400 on the substrate 100 at least partially overlaps an orthographic projection of the opening on the substrate 100. The photoresist layer 500 is located on a surface of the sacrificial layer 400 away from the substrate 100 (with reference to FIG. 2C for a schematic structural diagram).

According to the embodiments of the present disclosure, more specifically, a way of forming the sacrificial layer 400 and the photoresist layer 500 is not particularly limited. With a specific embodiment in the present disclosure as an example, a specific way of forming the sacrificial layer 400 and the photoresist layer 500 in the present disclosure is described below.

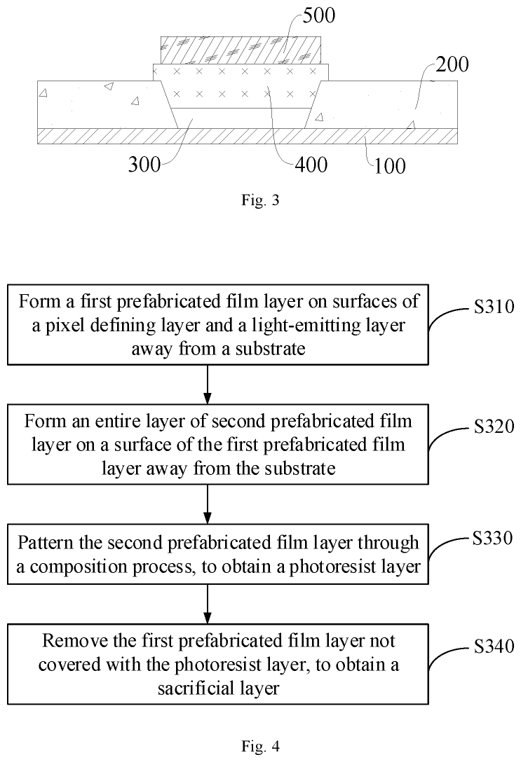

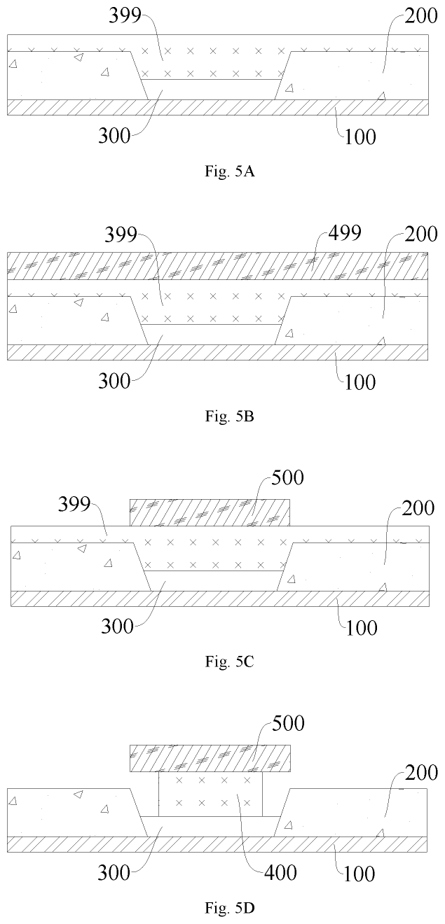

According to the embodiments of the present disclosure, with reference to FIGS. 4, 5A, 5B, 5C and 5D, the step that the sacrificial layer 400 and the photoresist layer 500 are formed on the surface of the light-emitting layer 300 away from the substrate 100 further includes the following steps.

S310: a first prefabricated film layer 399 is formed on the surfaces of the pixel defining layer 200 and the light-emitting layer 300 away from the substrate 100 (with reference to FIG. 5A for a schematic structural diagram).

According to the embodiments of the present disclosure, a specific process of forming the first prefabricated film layer 399 on the surfaces of the pixel defining layer 200 and the light-emitting layer 300 away from the substrate 100 may be coating, and specific conditions and parameters of the coating may be flexibly selected by those skilled in the art according to actual requirements, which will not be repeated herein. In addition, it should be noted that, in order to protect the light-emitting layer 300 against damage, coating of the first prefabricated film layer 399 may be conducted under protection of inert gas, and the inert gas may be nitrogen. In this way, operations are simple, convenient and easy to implement, and industrial production is feasible.

S320: an entire layer of second prefabricated film layer 499 is formed on a surface of the first prefabricated film layer 399 away from the substrate 100 (with reference to FIG. 5B for a schematic structural diagram).

According to the embodiments of the present disclosure, a specific process of forming the entire layer of second prefabricated film layer 499 on the surface of the first prefabricated film layer 399 away from the substrate 100 may be coating, and specific conditions and parameters of coating may be flexibly selected by those skilled in the art according to actual requirements, which will not be repeated herein. In this way, operations are simple, convenient and easy to implement, and industrial production is feasible.

S330: the second prefabricated film layer 499 is patterned through a composition process, so as to obtain the photoresist layer 500 (with reference to FIG. 5C for a schematic structural diagram).

According to the embodiments of the present disclosure, the composition process may include steps of exposing and developing the second prefabricated film layer 499, so as to form the photoresist layer 500. Specifically, when an exposure step is conducted, an exposure position may be selected according to different characteristics of photoresist, that is, differences between positive photoresist and negative photoresist; and after the exposure step is conducted, development is conducted in a developing solution. In addition, specific process parameters of each step in the composition process are process parameters of a conventional composition process, which will not be repeated herein. In this way, fabrication processes are simple, convenient and easy to implement, and industrial production is feasible.

S340: the first prefabricated film layer 399 not covered with the photoresist layer 500 is removed, so as to obtain the sacrificial layer 400 (with reference to FIG. 5D for a schematic structural diagram).

According to the embodiments of the present disclosure, a specific process of removing the first prefabricated film layer 399 not covered with the photoresist layer 500 may include steps of taking the photoresist layer 500 as a mask, and using the developing solution to develop the first prefabricated film layer 399, so as to obtain the sacrificial layer 400. In this way, fabrication processes are simple, convenient and easy to implement, and industrial production is feasible. In addition, a specific structure of the sacrificial layer 400 of the present disclosure may be better formed, which is conducive to subsequent use.

In this way, the sacrificial layer 400 and the photoresist layer 500 are formed on the surface of the light-emitting layer 300 away from the substrate 100. After the above structure is formed, the cathode of the display substrate may be formed in the following two steps.

S400: a first metal layer 600 is formed on surfaces of the pixel defining layer 200 and the photoresist layer 500 away from the substrate 100 (with reference to FIG. 2D for a schematic structural diagram).

According to the embodiments of the present disclosure, a specific process of forming the first metal layer 600 on the surfaces of the pixel defining layer 200 and the photoresist layer 500 away from the substrate 100 may include vacuum evaporation, chemical vapor deposition, etc. Process parameters of the vacuum evaporation, chemical vapor deposition, etc. are process parameters of conventional vacuum evaporation, chemical vapor deposition, etc., which will not be repeated herein. In this way, fabrication processes are simple, convenient and easy to implement, and industrial production is feasible.

According to the embodiments of the present disclosure, a thickness of the first metal layer 600 may be not smaller than 10 nm. The thickness of the first metal layer 600 is within the above range, such that an IR drop problem of the cathode of the fabricated display substrate may be solved. Furthermore, the thickness of the first metal layer 600 may be 20 nm-30 nm, and specifically, may be 20 nm, 22 nm, 24 nm, 26 nm, 28 nm, 30 nm, etc. In this way, the cathode of the fabricated display substrate on the surface of the pixel defining layer 200 is made thicker, such that an electric conductivity may be further improved, a resistance of the cathode is smaller, an IR drop is lower, then uniformity of pictures during display is high, and a display effect is desirable; and moreover, the cathode may not be too thick, so as to be in line with a development trend of a thin display substrate.

According to the embodiments of the present disclosure, a material of the first metal layer 600 may include a material of a cathode of a conventional display substrate, such as magnesium or silver, which will not be repeated herein. In this way, the material is widely sourced, easily available and low in cost.

S500: the sacrificial layer 400, the photoresist layer 500, and the first metal layer 600 located on the surface of the photoresist layer 500 away from the substrate 100 are removed, and the opening 210 is exposed (with reference to FIG. 2E for a schematic structural diagram).

According to the embodiments of the present disclosure, a specific process of removing the sacrificial layer 400, the photoresist layer 500, and the first metal layer 600 located on the surface of the photoresist layer 500 away from the substrate 100 may include step of placing the display substrate in a stripping solution capable of dissolving the sacrificial layer 400. The stripping solution may only dissolve the sacrificial layer 400, without dissolving the photoresist layer 500 or influencing a resistance of the first metal layer 600. Specifically, a material of the stripping solution may selected from stripping solutions for fluorine-based high-polymer materials produced by the Orthogonal Company of the United States, and may specifically be hydrofluoroether. In this way, after the sacrificial layer 400 is dissolved, the photoresist layer 500 and the first metal layer 600 thereon may be removed at the same time, such that operations are simple, convenient and easy to implement, and industrial production is feasible.

S600: a second metal layer 700 is formed in the opening and on a surface of the first metal layer 600 away from the substrate 100, the first metal layer 600 and the second metal layer 700 jointly constituting the cathode of the display substrate (with reference to FIG. 2F for a schematic structural diagram).

According to the embodiments of the present disclosure, a specific process of forming the second metal layer 700 in the opening and on the surface of the first metal layer 600 away from the substrate 100 may include vacuum evaporation, chemical vapor deposition, etc. Process parameters of the vacuum evaporation, chemical vapor deposition, etc. are process parameters of conventional vacuum evaporation, chemical vapor deposition, etc., which will not be repeated herein. In this way, fabrication processes are simple, convenient and easy to implement, and industrial production is feasible.

According to the embodiments of the present disclosure, a thickness of the second metal layer 700 may be 5 nm-15 nm, and specifically, may be 5 nm, 7 nm, 9 nm, 10 nm, 11 nm, 12 nm, 15 nm, etc. In addition, the thickness of the second metal layer 700 is generally smaller than the thickness of the first metal layer 600. In this way, the cathode of the fabricated display substrate may be made thinner in the opening, and light-emitting efficiency is high, such that a display effect may be made desirable; and in addition, the cathode on the surface of the pixel defining layer 200 is thicker, such that high light-emitting efficiency and a smaller resistance and a lower IR drop of the cathode may be achieved at the same time, uniformity of pictures during display may be high, a display effect may be desirable, moreover, a mask cannot be wasted, and costs are low.

According to the embodiments of the present disclosure, a material of the second metal layer 700 may include a material of the cathode of a conventional display substrate, such as magnesium or silver, which will not be repeated herein. In this way, the material is widely sourced, easily available and low in cost.

According to the embodiments of the present disclosure, in conclusion, in the present disclosure, the sacrificial layer 400 and the photoresist layer 500 are formed on at least part of the surface of the light-emitting layer 300 away from the substrate 100, such that a mask that may be removed in a subsequent step is formed on the surface of the light-emitting layer 300; and the photoresist layer may function as a mask. Specifically, in subsequent steps, the cathode may be formed in two steps as follows: first, when the sacrificial layer 400 and the photoresist layer 400 exist in the opening, the first metal layer is formed, and the photoresist layer 500 may make the first metal layer that should be formed in the opening be formed on the surface of the photoresist layer 500 away from the substrate 100; and until the sacrificial layer 400, the photoresist layer 500, and the first metal layer formed on the surface of the photoresist layer 500 away from the substrate 100 are removed, the second metal layer is formed. In this case, the second metal layer may be normally formed in the opening since the opening is not shielded by the photoresist layer 500. In this way, the surface of the pixel defining layer 200 away from the substrate 100 is provided with two metal layers, that is, the first metal layer and the second metal layer; and the opening is internally provided with only one metal layer, that is, the second metal layer, such that the cathode of the fabricated display substrate is made thinner in the opening and thicker on the surface of the pixel defining layer 200, high light-emitting efficiency and a smaller resistance and a lower IR drop of the cathode may be achieved at the same time, uniformity of pictures during display may be high, a display effect may be desirable, moreover, a mask cannot be wasted, and costs are low.

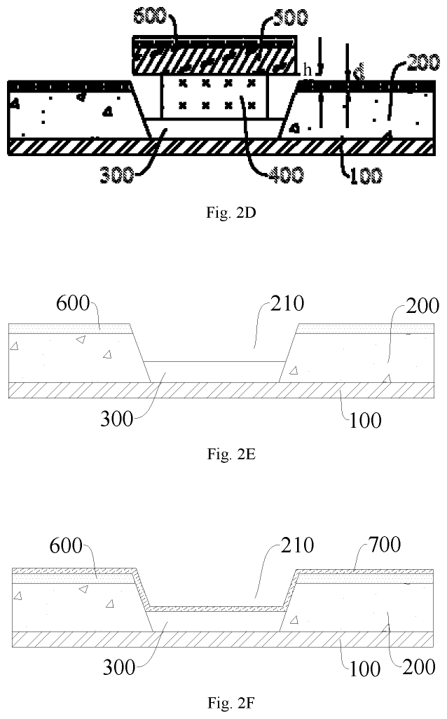

According to the embodiments of the present disclosure, furthermore, a relative positional relationship between the sacrificial layer 400 and the photoresist layer 500 has a significant influence on subsequent formation of the first metal layer and the second metal layer. After extensive experimental research, the inventor finds that the orthographic projection of the sacrificial layer 400 on the substrate 100 may be located in an orthographic projection of the photoresist layer 500 on the substrate 100 (with reference to FIG. 2C for a schematic structural diagram). In some other embodiments of the present disclosure, the orthographic projection of the photoresist layer 500 on the substrate 100 may also be located in the orthographic projection of the sacrificial layer 400 on the substrate 100 (with reference to FIG. 3 for a schematic structural diagram).

According to the embodiments of the present disclosure, specifically, after the sacrificial layer 400 and the photoresist layer 500 are formed in the way as shown in FIG. 2C, with reference to FIG. 2D, based on the above, there is still a gap between an outline of the orthographic projection of the photoresist layer 500 on the substrate 100 and an outline of the orthographic projection of the sacrificial layer 400 on the substrate 100, and when the first metal layer 600 is formed, the first metal layer 600 formed on the surface of the pixel defining layer 200 away from the substrate 100 and the first metal layer 600 formed on the surface of the photoresist layer 500 away from the substrate 100 may be completely disconnected. Therefore, the first metal layer 600 on the surface of the photoresist layer 500 away from the substrate 100 may be completely removed in the subsequent step, such that the cathode on the surface of the pixel defining layer 200 in the fabricated display substrate is thicker, and an IR drop of the cathode may be further reduced, uniformity of pictures during display is high, and a display effect is desirable.

According to the embodiments of the present disclosure, based on the above, in order to further completely remove the first metal layer 600 on the surface of the photoresist layer 500 away from the substrate 100 in the subsequent step, it is necessary to refer to FIG. 2D and to make a distance h between the surface of the photoresist layer 500 close to the substrate 100 and the surface of the pixel defining layer 200 away from the substrate 100 greater than a thickness d of the formed first metal layer 600. In this way, even after the first metal layer 600 is formed, there is still a distance between a lower surface of the photoresist layer 500 and an upper surface of the first metal layer 600. Therefore, when the photoresist layer 500 and the first metal layer 600 thereon are removed in the subsequent step, the first metal layer 600 located on the surface of the pixel defining layer 200 cannot be influenced at all, such that an IR drop of the cathode is lower and a display effect is desirable in the fabricated display substrate.

According to the embodiments of the present disclosure, in addition, according to a structure shown in FIG. 2D, the thicknesses of the sacrificial layer 400 and the photoresist layer 500 also have a certain influence on whether the first metal layer formed on the surface of the photoresist layer 500 away from the substrate 100 may be completely removed. In some embodiments of the present disclosure, the thickness of the sacrificial layer 400 may be 0.2 μm-1.5 μm, and specifically, may be 0.2 μm, 0.5 μm, 1 μm, 1.5 μm, etc. In addition, the thickness of the photoresist layer 500 may be 0.5 μm-2 μm, and specifically, may be 0.5 μm, 1 μm, 1.5 μm, 2 μm, etc. When the thicknesses of the sacrificial layer 400 and the photoresist layer 500 are in the above range, the first metal layer 600 located on the surface of the photoresist layer 500 away from the substrate 100 is easier to remove in the subsequent step, which is conducive to subsequent use.

According to the embodiments of the present disclosure, specifically, in another specific implementation, with reference to FIG. 3, the orthographic projection of the sacrificial layer 400 on the substrate 100 covers the orthographic projection of the opening on the substrate 100. When the first metal layer is formed, the sacrificial layer 400 may better prevent the opening from internally forming the first metal layer, such that the cathode located in the opening in the fabricated display substrate may be made thinner, and further light-emitting efficiency of the display substrate is higher.

According to the embodiments of the present disclosure, furthermore, for a specific material of forming the sacrificial layer 400, after rigorous screening and experiments, the inventor finds that when a material of the sacrificial layer 400 includes a fluorine-containing high-polymer material, a whole process of forming the sacrificial layer 400 on the surface of the light-emitting layer 300 and then removing the sacrificial layer cannot damage the light-emitting layer 300 and influence a display effect of the fabricated display substrate. Specifically, a specific type of the fluorine-containing high-polymer material is not particularly limited. For example, the material may be selected from fluorine-based high-polymer materials developed by the Orthogonal Company of the United States.

In another aspect of the present disclosure, the present disclosure provides a display substrate. According to the embodiments of the present disclosure, the display substrate is fabricated through the above method. With reference to FIG. 2F, the display substrate includes a substrate 100, a pixel defining layer 200, a light-emitting layer 300 and a cathode. The pixel defining layer 200 defines an opening 210.

The cathode includes: a first metal layer 600, arranged on a surface of the pixel defining layer 200 away from the substrate 100; and a second metal layer 700, arranged in the opening 210 and on a surface of the first metal layer 600 away from the substrate 100.

The cathode of the display substrate is thinner in the opening and thicker on a surface of the pixel defining layer, such that high light-emitting efficiency and a smaller resistance and a lower IR drop of the cathode may be achieved at the same time, uniformity of pictures during display may be high, a display effect may be desirable, moreover, a mask cannot be wasted, and costs are low.

According to the embodiments of the present disclosure, those skilled in the art can understand that a relative positional relationship between the substrate 100, the pixel defining layer 200, the light-emitting layer 300, etc. is as described as above, which will not be repeated herein.

Specifically, as shown in FIG. 2F, a section of a part of the pixel defining layer 200 between adjacent openings 210 perpendicular to a surface of the substrate 100 is a regular trapezoid (which is narrow in an upper part and wide in a lower part); and the first metal layer 600 only covers a top surface of the regular trapezoid. The second metal layer 700 covers a top surface and a side wall of the first metal layer 600 and a side wall of the regular trapezoid.

According to the embodiments of the present disclosure, as described above, in the display substrate of the present disclosure, a thickness of the first metal layer 600 may be not smaller than 10 nm, and furthermore, the thickness of the first metal layer 600 may be 20 nm-30 nm; and a thickness of the second metal layer 700 may be 5 nm-15 nm, and the thickness of the first metal layer 600 is generally greater than the thickness of the second metal layer 700, which are specifically the same as the related description in the fabrication method for the display substrate and will not be repeated herein.

According to the embodiments of the present disclosure, the display substrate may further include other necessary structures and compositions, such as pixel electrodes, which may be supplemented and designed by those skilled in the art according to specific types and use requirements of the display substrate and will not be repeated herein.

In another aspect of the present disclosure, the present disclosure provides a display apparatus. According to the embodiments of the present disclosure, the display apparatus includes the display substrate. The display apparatus has high uniformity of pictures during display, a desirable display effect and a low cost.

According to the embodiments of the present disclosure, in addition to the display substrate, the display apparatus may further include other necessary structures and compositions, which can be supplemented and designed by those skilled in the art according to specific types and use requirements of the display apparatus and will not be repeated herein.

According to the embodiments of the present disclosure, specific types of the display apparatus are not particularly limited, including but not limited to mobile phones, tablet computers, wearable devices, game machines, televisions, vehicle-mounted displays, etc.

In the description of the present disclosure, it should be understood that the terms “first” and “second” are only used for describing purposes and cannot be understood as indicating or implying relative importance or implicitly indicating the number of indicated technical features. Therefore, the features defined with “first” and “second” can explicitly or implicitly include one or more features. In the description of the present disclosure, the term “a plurality of” means two or more, unless otherwise specified.

In the description, the description with reference to the terms such as “an embodiment”, “some embodiments”, “examples”, “specific examples”, or “some examples” means that specific features, structures, materials, or characteristics described in combination with the embodiment(s) or example(s) are included in at least one embodiment or example of the present disclosure. In the description, schematic expressions of the above terms are not necessarily directed to the same embodiment or example. Furthermore, the specific features, structures, materials, or characteristics described herein can be combined in any suitable manner in any one or more embodiments or examples. In addition, without any contradiction, those skilled in the art can bind and combine different embodiments or examples and features of the different embodiments or examples described in the description.

Although the embodiments of the present disclosure are shown and described above, it should be understood that the embodiments are illustrative and cannot be construed as limitations to the present disclosure, and those skilled in the art can make changes, modifications, substitutions and variations to the embodiments within the scope of the present disclosure.

1. A method for fabricating a display substrate, comprising:
forming a pixel defining layer on a surface of one side of a substrate, wherein the pixel defining layer defines an opening;
forming a light-emitting layer on one side of the pixel defining layer away from the substrate;
forming a sacrificial layer and a photoresist layer on a surface of the light-emitting layer away from the substrate, wherein an orthographic projection of the sacrificial layer on the substrate at least partially overlaps an orthographic projection of the opening on the substrate, and the photoresist layer is located on a surface of the sacrificial layer away from the substrate;
forming a first metal layer on surfaces of the pixel defining layer and the photoresist layer away from the substrate;
removing the sacrificial layer, the photoresist layer, and the first metal layer located on the surface of the photoresist layer away from the substrate, and exposing the opening; and
forming a second metal layer in the opening and on a surface of the first metal layer away from the substrate, wherein the first metal layer and the second metal layer jointly constitute a cathode of the display substrate.

2. The method according to claim 1, wherein the orthographic projection of the sacrificial layer on the substrate is located in an orthographic projection of the photoresist layer on the substrate.

3. The method according to claim 2, wherein a gap is between an outline of the orthographic projection of the photoresist layer on the substrate and an outline of the orthographic projection of the sacrificial layer on the substrate.

4. The method according to claim 1, wherein a distance between a surface of the photoresist layer close to the substrate and a surface of the pixel defining layer away from the substrate is greater than a thickness of the first metal layer.

5. The method according to claim 1, wherein the orthographic projection of the sacrificial layer on the substrate covers the orthographic projection of the opening on the substrate.

6. The method according to claim 1, wherein the sacrificial layer satisfies at least one of the following conditions that:
a material comprises a fluorine-containing high-polymer material; and
a thickness is 0.2 μm-1.5 μm.

7. The method according to claim 1, wherein a thickness of the photoresist layer is 0.5 μm-2 μm.

8. The method according to claim 1, wherein the forming the sacrificial layer and the photoresist layer on the surface of the light-emitting layer away from the substrate further comprises:
forming a first prefabricated film layer on the surfaces of the pixel defining layer and the light-emitting layer away from the substrate;
forming an entire layer of second prefabricated film layer on a surface of the first prefabricated film layer away from the substrate;
patterning the second prefabricated film layer through a composition process, to obtain the photoresist layer; and
removing the first prefabricated film layer not covered with the photoresist layer, to obtain the sacrificial layer.

9. A display substrate, comprising a substrate, a pixel defining layer, a light-emitting layer and a cathode, wherein the pixel defining layer defines an opening; and
the cathode comprises:
a first metal layer, arranged on a surface of the pixel defining layer away from the substrate; and
a second metal layer, arranged in the opening and on a surface of the first metal layer away from the substrate.

10. The display substrate according to claim 9, wherein a section of a part of the pixel defining layer between adjacent openings perpendicular to a surface of the substrate is a regular trapezoid; and
the first metal layer only covers a top surface of the regular trapezoid.

11. The display substrate according to claim 10, wherein the second metal layer covers a top surface of the first metal layer and a side wall of the first metal layer and a side wall of the regular trapezoid.

12. The display substrate according to claim 9, wherein a thickness of the first metal layer is not smaller than 10 nm.

13. The display substrate according to claim 12, wherein a thickness of the first metal layer is 20 nm-30 nm; and a thickness of the second metal layer is 5 nm-15 nm.

14. The display substrate according to claim 9, wherein a thickness of the first metal layer is greater than a thickness of the second metal layer.

15. A display apparatus, comprising a display substrate, wherein the display substrate comprises:
a substrate, a pixel defining layer, a light-emitting layer and a cathode, wherein the pixel defining layer defines an opening; and
the cathode comprises:
a first metal layer, arranged on a surface of the pixel defining layer away from the substrate; and
a second metal layer, arranged in the opening and on a surface of the first metal layer away from the substrate.

16. The display apparatus according to claim 15, wherein a section of a part of the pixel defining layer between adjacent openings perpendicular to a surface of the substrate is a regular trapezoid; and
the first metal layer only covers a top surface of the regular trapezoid.

17. The display apparatus according to claim 16, wherein the second metal layer covers a top surface of the first metal layer and a side wall of the first metal layer and a side wall of the regular trapezoid.

18. The display apparatus according to claim 15, wherein a thickness of the first metal layer is not smaller than 10 nm.

19. The display apparatus according to claim 18, wherein a thickness of the first metal layer is 20 nm-30 nm; and a thickness of the second metal layer is 5 nm-15 nm.

20. The display apparatus according to claim 15, wherein a thickness of the first metal layer is greater than a thickness of the second metal layer.
